(19) United States
(12) Patent Application Publication
(10) Pub. No.: US 2013/0106193 A1
(43) Pub. Date: May 2, 2013

(54) HYBRID WIND AND SOLAR ENERGY DEVICE

(71) Applicant: Thomas Patrick Bryson, Brantford (CA)

(72) Inventor: Thomas Patrick Bryson, Brantford (CA)

(21) Appl. No.: 13/695,110

(22) PCT Filed: Apr. 29, 2011
(86) PCT No.: PCT/CA2011/000471

§ 371 Date: Jan. 17, 2013

Related U.S. Application Data
(60) Provisional application No. 61/329,134, filed on Apr. 29, 2010.
(60) Provisional application No. 61/475,729, filed on Apr. 15, 2011.

(51) Int. Cl. F03D 9/00; H01L 31/058; H02J 5/00

(52) U.S. Cl. CPC F03D 9/002; H02J 5/00; H01L 31/0583
USPC 307/73; 290/55; 136/244

(57) ABSTRACT

Disclosed is a hybrid wind-solar energy device comprising: a) a wind-capture assembly comprising: i) one or more wind sails evenly distributed circumferentially around a central axis thereof; and ii) a solar-energy capture means on an outer surface of the wind-capture assembly; and c) a turbine assembly comprising an anchoring base, an electrical generator and an output shaft; the wind-capture assembly rotatably mounted on the output shaft and coupled thereto; the hybrid wind-solar energy device configured to convert energy harnessed by the wind capture assembly to electrical energy, wherein: interaction of the one or more wind sails with wind induces rotation of the wind-capture assembly and turbine assembly around the central axis; and the outer surface of the wind capture assembly is directly exposed to sunlight throughout daylight hours.

FIG. 1 illustrates an exploded view of an embodiment of a hybrid wind-solar device (5) of the invention. The outer wind-capture assembly (10) consists of a fabricated or formed outer structure. On the exterior surface of the outer wind-capture assembly (10), are affixed solar PV panels, membranes, or a similarly suitable conductive skin to collect solar energy. The solar energy is transferred via a harvesting wire network for use as required.

The turbine assembly (15) includes an anchoring base (20) for securing to an immovable surface; an output shaft (25) emanating from the anchoring base (20); and a turbine (35) positioned on the axis of the output shaft (25). In the embodiment shown in FIG. 1, the output shaft (25) is fitted with no less than two sets of precision bearings.

Assembly of the hybrid wind-solar device (5) is completed by mounting the outer wind-capture assembly (10) over the turbine assembly (15). Bearing sockets (not shown) in the outer wind-capture assembly (10) are secured with the bearings on the output shaft (25) of the turbine assembly (15).

In an alternate embodiment, the wind-capture assembly can be directly affixed to an output shaft, without the need for additional bearings, gears, pulleys or other such mechanical drive system to convey power from the turbine (35) to the generator.

The assembled device (5) is attached, via the anchoring base (20), to an appropriate surface. This can include, but is not limited to the ground, a roof, or such other location as required to securely anchor the invention and eliminate unwanted movement.

In addition, all necessary electrical connections are made to transfer the output of the solar PV panels and the output of the turbine (35) via brushes, wires or such other method as practicable to send the current to an inverter, rectifier, control panel, battery bank or grid tied inverter, the device is ready to generate electrical energy. The energy can be transferred, for example, to a power reservoir such as a battery bank, or fed directly into Conventional windmills or wind turbines create energy from dynamic lift caused by kinetic energy from the wind passing over an airfoil (blade) thereby initiating rotation. If a cross-section of the swept area of by conventional 3-blade wind turbine is examined, it is evident that very little of the available wind moving through the swept area comes into contact with the blades. The area of the blades in relationship to the swept area is less than 3%; that is, up to 97% of the available energy from the wind passes through between the blades without converting any of its kinetic energy to electricity.

Unlike conventional wind generating devices, the present hybrid wind-solar device captures the wind and all of its potential and kinetic energy by encapsulating it within the “pockets” or “sails” on the downwind side, and by creating a low pressure area on the “upwind” side—similar to a yacht tacking into the wind. This is illustrated in FIGS. 6A and 6B, which respectively show perspective and top plan views of a 3-sail hybrid wind-solar device as it rotates due to kinetic energy from the wind.

For illustration purposes, the wind direction is “into” the device in FIG. 6A, and “up” in FIG. 6B, causing the device to rotate clockwise as wind is “captured” in the left side wind pockets or sails. By “encapsulating” the wind energy within the left side fin cavities, the device is more efficient than a traditional wind turbine that has wind merely solely passing over the blade.

A result of the design is to provide for an efficient vertical wind turbine that captures and converts a high percentage of available kinetic energy from the wind into useable electricity. The consequence of this process is a device that turns on a central axis or vertical shaft, which is attached either directly or indirectly through mechanical means, to an electrical generator or machine capable of converting kinetic energy into electrical power.

The wind-capture device acts as a prime mover to turn a generator shaft which is typically attached to an armature with a set of windings on an iron core. Through electromagnetic induction, the rotating shaft causes a voltage to be induced in the

### TECHNICAL BACKGROUND

The present disclosure relates to the field of renewable energy. In particular, the present disclosure relates to generating electrical energy from solar energy and wind energy.

### BACKGROUND

There are a number of energy converters that claim to transform thermal increases from solar energy into electricity by way of photovoltaic technology, commonly referred to as “solar panels”. Although considerable development has been targeted at this technology, it still remains an inefficient means of generating electricity. There are significant up-front costs, as well as a long period for recouping initial investment costs.

In addition, wind can be harvested into a useable output, as in the case of, for example, sailing ships and windmills. Currently, the focus on wind and wind-power has become synonymous with the green energy movement as a way of generating renewable eco-friendly electricity.

Due to the unpredictability of the sun and the wind energy available in a given location, site specification is important for maximizing the output of both wind and solar technologies. In many instances, devices that employ these technologies are located in remote regions far away from the end user; significant new infrastructure is required to get power to locations where it is used.

U.S. Pat. No. 7,638,891 (issued Dec. 29, 2009 to Fein et al.) discloses a method and system for providing an energy gathering sheet to harness and provide energy to homes, businesses, and/or a utility grid. The energy gathering sheet receives very small solar or wind energy gathering devices (micrometer to nanometer range) or any combination thereof.

U.S. Pat. No. 7,045,702 (issued May 6, 2006 to Kashyap) discloses a solar-paneled windmill is provided having aerodynamic fan blades provided with solar panels. The windmill produces electricity using wind energy and solar energy.

U.S. Patent Application No. 2009/0244890A1 (Pelken et al; published Oct. 1, 2009) discloses a wind-powered device in which a turbine generator has one or more wind turbines for generating energy and a series of aerodynamically-designed plates located above and below each turbine for focusing and converging the wind inwardly. Solar panels may be provided in conjunction with the turbine generator to provide an additional source of energy.

U.S. Patent Application No. 2008/0047270A1 (Gilbert; published Feb. 28, 2008) discloses a solar windmill that combines a wind turbine and solar energy collector. Solar panels are mounted on the surfaces of a wind turbine such that the combined energy from the wind turbine and the solar panels are provided as an output.

German Patent Application No. 10212354A1 (published Oct. 2, 2003) discloses a combined solar-wind power generator with wind propeller for converting wind into electric energy, with solar cells fitted to rotor blade surfaces, at least partly.

Japanese Patent Application No. 2006105107 (A) (Yamazaki; published Apr. 20, 2006) discloses a photovoltaic/wind power generation device with a generator provided with a vertical shaft type wind mill, and each blade of the wind mill is composed of photovoltaic battery panel in a shape of transparent plate having a photovoltaic battery inside.

Japanese Patent Application No. 2005083327 (A) (Kurokawa et al; published Mar. 31, 2005) discloses a power generating device that combines photovoltaic power generation maintaining generating efficiency of a solar cell at a high level, with wind power generation using air current energy generated by solar light energy or the like.

U.S. Pat. No. 4,553,037 (issued Nov. 12, 1985 to Veazey) discloses a Vertical Axis Wind Turbine (VAWT) of the several Darrieus designs in conjunction with roll-up or permanently-mounted solar cells combined in a hybrid or used separately to provide power to a battery bank or other storage device.

The present disclosure pertains to a hybrid system incorporating aspects of both wind and solar energy systems to create an efficient generating platform containing a combination of solar photovoltaic and wind turbine technologies integrated into a common control panel management system that stores and transforms energy to an electric current. In addition, the photovoltaic (PV) efficiency is increased by permitting the surface of the device to be exposed to the sun's rays at all times without the use of mechanical or electrical actuation. There is a reduction of energy loss due to rain, ice and snow build-up on the PV panel(s) by centrifugal shedding. Furthermore, wind damage of conventional PV panels is significantly reduced or eliminated altogether by conversion of kinetic energy acting upon the panel into a rotary motion that generates additional electricity via an internal turbine. There is also a reduction of cost, due to the fact that expensive fabricated mounting systems and automated sun seeker tracking systems are not required.

### SUMMARY

The disclosure pertains generally to an alternative energy device with a useable output of work producing minimal environmental impact. More specifically, the present application provides a rotating alternate energy device that is scalable, and can be adjusted dimensionally to conform to specifications of size, space and function. The device includes a unique design to increase its efficiency over existing generating devices by way of an integrated combination of solar panel and wind turbine technologies.

According to one aspect of the disclosure, there is provided a hybrid wind-solar energy device comprising: a) a wind-capture assembly comprising: i) one or more wind sails evenly distributed circumferentially around a central axis thereof; and ii) a solar-energy capture means on an outer surface of the wind-capture assembly; and c) a turbine assembly comprising an anchoring base, an electrical generator and an output shaft; the wind-capture assembly rotatably mounted on the output shaft and coupled thereto; the hybrid wind-solar energy device configured to convert energy harnessed by the wind capture assembly to electrical energy, wherein: interaction of the one or more wind sails with wind induces rotation of the wind-capture assembly and turbine assembly around the central axis; and the outer surface of the wind capture assembly is directly exposed to sunlight throughout daylight hours.

The aforementioned wind capture assembly can have: a) a cross-sectional area transverse to the central axis; b) a first extremity along the central axis; and c) a second extremity along the central axis; such that the cross-sectional area decreases from the first extremity to the second extremity. In addition, the wind-capture assembly may have a conical, pyramidal, or parabolic trumpet shape; the number of wind sails may be three or four. Furthermore, the wind sail can have a form of a flat panel, parabolic arc, circular arc or bi-circular arc. Where the number of wind sails is one, and the wind sail has a helical shape. The aforementioned solar-energy capture means can be selected from the group consisting of solar panels, photovoltaic panels, cells, discs, skins, films, sprays and any combination of thereof. Alternatively, the solar-energy capture means can be flexible or rigid solar panels. The electrical energy can be stored, loaded onto a grid, directed to one or more electrical appliances, or any combination thereof.

According to another aspect of the disclosure, there is provided a method for generating electricity using a hybrid wind-solar device, the method comprising: a) providing a wind-capture assembly for capturing wind energy, the wind-capture assembly comprising one or more wind sails evenly distributed circumferentially around a central axis thereof; b) rotatably coupling the wind-capture assembly to a turbine assembly, the turbine assembly comprising an anchoring base, an electrical generator and a vertical out shaft; c) providing solar-capture means on an outer surface of the wind-capture assembly, the outer surface of the wind-capture assembly being exposed to sunlight throughout daylight hours; d) affixing the combined wind-capture assembly and turbine assembly via the anchoring base to a surface; e) inducing rotation of the wind-capture assembly and turbine assembly around the central axis by interaction of wind with the one or more wind sails; and f) providing electrical circuitry to convert energy harnessed by the wind capture assembly to electrical energy.

The aforementioned wind capture assembly can have: a) a cross-sectional area transverse to the central axis; b) a first extremity along the central axis; and c) a second extremity along the central axis; such that the cross-sectional area decreases from the first extremity to the second extremity. In addition, the wind-capture assembly may have a conical, pyramidal, or parabolic trumpet shape; the number of wind sails may be three or four. Furthermore, the wind sail can have a form of a flat panel, parabolic arc, circular arc or bi-circular arc. Where the number of wind sails is one, and the wind sail has a helical shape. The aforementioned solar-energy capture means can be selected from the group consisting of solar panels, photovoltaic panels, cells, discs, skins, films, sprays and any combination of thereof. Alternatively, the solar-energy capture means can be flexible or rigid solar panels. The electrical energy can be stored, loaded onto a grid, directed to one or more electrical appliances, or any combination thereof.

According to yet another aspect of the disclosure, there is provided a renewable energy device comprising: a) a wind-capture assembly comprising one or more wind sails evenly distributed circumferentially around a central axis thereof; and b) a turbine assembly comprising an anchoring base, an electrical generator and an output shaft; the wind-capture assembly rotatably mounted on the output shaft and coupled thereto; the hybrid wind-solar energy device configured to convert energy harnessed by the wind capture assembly to electrical energy, wherein: interaction of the one or more wind sails with wind induces rotation of the wind-capture assembly and turbine assembly around the central axis.

In addition to the foregoing attributes, the hybrid wind-solar device possesses benefits over standard wind or solar systems.

Conventional wind turbines require considerable height requirements, which are often expensive, unsightly and difficult to service. However, the present hybrid wind-solar device mounts directly on a anchoring base and can be affixed at ground level or on a roof, on hi-way barriers, overhead signs, advertising placards, or any location where portable power may be required.

Conventional wind turbines are exposed to the elements where reliability and cost is impacted by maintenance requirements, broken blades, icing, furling, and/or corrosion of electrical components. However, electrical components of the present hybrid wind-solar device are located inside the device and away from the elements. Furthermore, conventional wind turbine propeller style blades are absent in the present device.

Conventional wind turbines typically require a tower or mounting system, and subsequent foundation, making them difficult and expensive to move or relocate once erected. On the other hand, the present hybrid wind-solar device is mobile and can be moved from location to location.

In addition, some conventional wind turbines require a yaw bearing. However, the present hybrid wind-solar device does not need to be pointed into the wind, nor does it require a yaw bearing. The present hybrid wind-solar device captures wind from any direction at any time, allowing capture of energy from gusting, spiralling or swirling winds.

Conventional PV systems often use flat solar panels in a fixed position, which are only efficient for the limited number of hours they are exposed to direct sunlight each day (as the sun crosses through the sky from dawn to dusk). However, the present hybrid wind-solar device is shaped to collect direct as well as indirect sunlight impinging on its surface at any time during the entire day. The geometry of the device is three-dimensional facing all directions, thus allowing for exposure to sunlight throughout the day. In addition, when the device spins, it exposes the PV surface to solar energy from whatever position the sun is in during the day.

Conventional curved or parabolic PV systems require additional cost of components to mechanically move them and allow tracking of the sun throughout the day thereby increasing efficiency. On the other hand, the present hybrid wind-solar device does not require any sun-tracking or actuation components.

Large PV panels in current solar-energy devices are susceptible to damage due to the forces of high wind. This necessitates the construction of elaborate and substantial fabricated brackets. The present hybrid wind-solar device captures these wind forces which may have otherwise damaged the panels, and in turn generates electrical power while continuing to expose its outer surface to the sun for generation of energy from the PV panels.

Most conventional PV panels lose efficiency when covered with rain, snow or ice. However, the physical design of the present hybrid wind-solar device, combined with its rotation and concomitant centrifugal forces, shed the surface of the device of obstructing foreign objects (such as rain, snow, ice, etc.)

The present hybrid wind-solar device can be scaled proportionately and easily relocated to areas where a portable supply of power is required. In addition, there is provided an alternate energy hybrid device encompassing the best features of wind and solar generation technology, while offering significant advantages over existing wind or solar systems.

There are many potential applications of the present hybrid wind-solar device. At a small scale, it can be used in remote locations to deliver a continuous supply of electricity to a cellular repeater station or microwave tower. It may also be mounted on a trailer or towed to location, providing emergency power in disaster zones, forward deployment military troop support, or as a portable power pack that can charge its batteries as it is towed to a remote location or rural abode void of a conventional power supply.

The foregoing summarizes the principal features of the hybrid wind and solar device, and some of its optional aspects and improvements over existing devices. The device may be further understood by the descriptions of the embodiments which follow. Whenever ranges of values are referenced within this specification, sub ranges therein are intended to be included within the scope unless otherwise stated. Where characteristics are attributed to one or another variant, unless otherwise indicated, such characteristics are intended to apply to all other variants where such characteristics are appropriate or compatible with such other variants.

### BRIEF DESCRIPTION OF THE DRAWINGS

Embodiments of the present invention will be further described, by way of example, with reference to the accompanying drawings, in which:

FIG. 1 illustrates an exploded perspective view of an embodiment of the invention.

FIGS. 2A-2C illustrate examples of different shapes of an outer wind-capture assembly for use with the embodiment shown in FIG. 1.

FIG. 3 illustrates a template for construction of a second embodiment.

FIGS. 4A-4C illustrate steps required for construction of a wind-capture assembly of the embodiment of FIG. 3.

FIG. 5 illustrates a top plan view of the embodiment shown in FIG. 4D.

FIGS. 6A and 6B illustrate rotation of a third embodiment.

FIG. 7 illustrates a circuit diagram of a hybrid wind-solar device.

### DETAILED DESCRIPTION

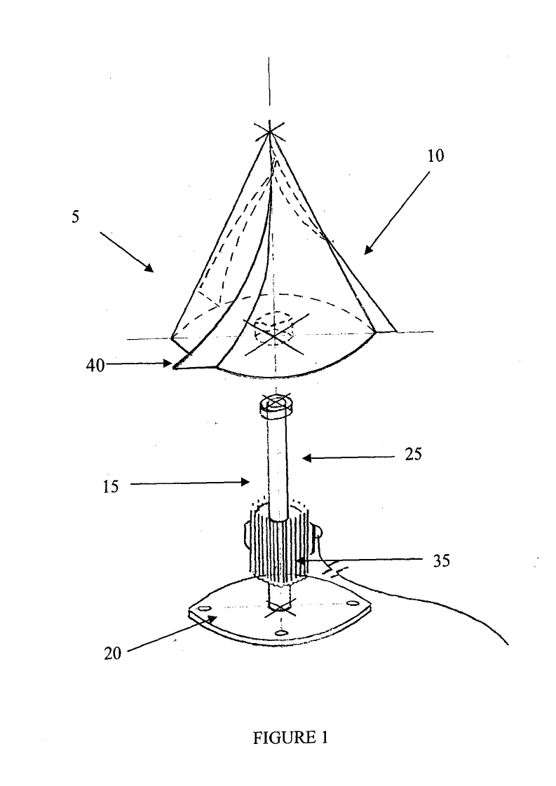

FIG. 1 illustrates an exploded view of an embodiment of a hybrid wind-solar device (5) of the invention. The outer wind-capture assembly (10) consists of a fabricated or formed outer structure. On the exterior surface of the outer wind-capture assembly (10), are affixed solar PV panels, membranes, or a similarly suitable conductive skin to collect solar energy. The solar energy is transferred via a harvesting wire network for use as required.

The turbine assembly (15) includes an anchoring base (20) for securing to an immovable surface; an output shaft (25) emanating from the anchoring base (20); and a turbine (35) positioned on the axis of the output shaft (25). In the embodiment shown in FIG. 1, the output shaft (25) is fitted with no less than two sets of precision bearings.

Assembly of the hybrid wind-solar device (5) is completed by mounting the outer wind-capture assembly (10) over the turbine assembly (15). Bearing sockets (not shown) in the outer wind-capture assembly (10) are secured with the bearings on the output shaft (25) of the turbine assembly (15).

In an alternate embodiment, the wind-capture assembly can be directly affixed to an output shaft, without the need for additional bearings, gears, pulleys or other such mechanical drive system to convey power from the turbine to the generator.

The assembled device (5) is attached, via the anchoring base (20), to an appropriate surface. This can include, but is not limited to the ground, a roof, or such other location as required to securely anchor the invention and eliminate unwanted movement.

In addition, all necessary electrical connections are made to transfer the output of the solar PV panels and the output of the turbine via brushes, wires or such other method as practicable to send the current to an inverter, rectifier, control panel, battery bank or grid tied inverter, the device is ready to generate electrical energy. The energy can be transferred, for example, to a power reservoir such as a battery bank, or fed directly into an electrical grid network, or diverted to an emersion heater for water. If electrical load is not required, the resulting energy can be dissipated into a grounded terminus.

Once assembled and with the anchoring base (20) secured, the PV panels on the outer wind-capture assembly (10) are exposed to direct sunlight. These solar panels then transfer the sun's energy through the system, with conversion to electrical energy for use as required. The wind pockets or sails (40) on the outer wind-capture assembly (10) induce rotation when the wind impacts on the wind pockets or sails (40). Since the outer wind-capture assembly (10) is coupled to the turbine assembly (15) via the bearings, it will rotate when instigated by the kinetic energy of the wind. This rotation initiates electrical generation through the turbine (35) and causes the full surface of the outer wind-capture assembly (10) to be exposed to the sun's rays, which in turn increases the efficiency of the PV output and is further complemented by the turbine output.

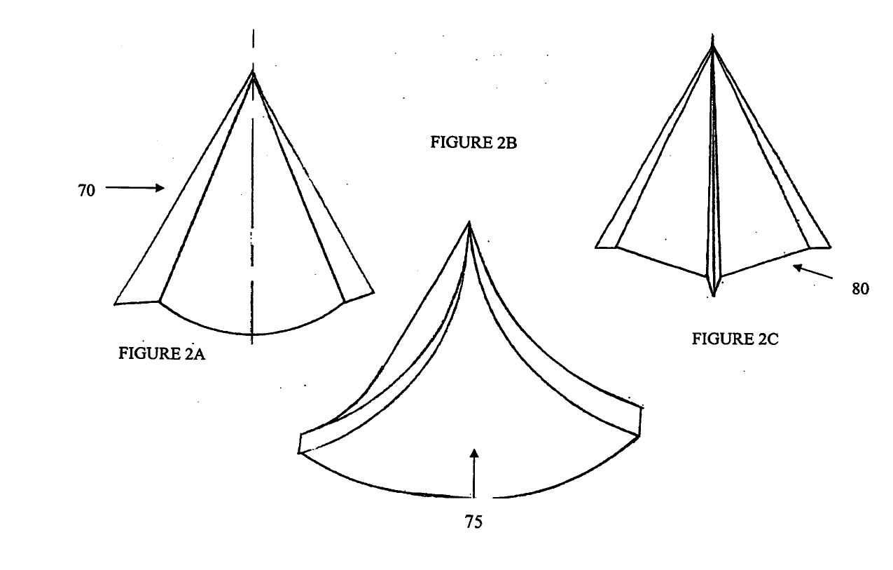

FIGS. 2A-2C illustrate examples of design shapes (70, 75, 80) of the outer wind-capture assembly for use with the embodiment shown in FIG. 1. These examples are representative only and do not limit the scope of the hybrid wind-solar device (5)

FIG. 2A illustrates a plan view of a conical-shaped (70) outer wind-capture assembly; FIG. 2B illustrates a perspective view of a parabolic trumpet-shaped (75) outer wind-capture assembly; and FIG. 2C illustrates a perspective view of a pyramidal-shaped (80) outer wind-capture assembly. The number of wind pockets or sails (40) is at minimum one. The shape of the wind pockets or sails (40) is such that it induces rotation of the wind-capture assembly (10). The design of the wind-capture assembly should ensure balanced rotation about the output shaft (25). Therefore, the shape of the wind-capture assembly (10) has some form of rotational symmetry about the output shaft (25). Other shapes of the outer wind-capture assembly may be used to achieve similar or acceptable results, and similar variants not shown, are intended to be encompassed within the scope of the device.

At least one sail surface must interact with the wind to initiate rotation and wind generation. For a single sail embodiment, a helical cone shape is used. This embodiment provides for a single sail that remains balanced while in use.

Since the device must stay in balance as it rotates, any number of sails are evenly distributed angularly around the anchoring base to ensure uniformity and balanced operation.

While there is a minimum of one sail there is no maximum number of sails. One, three or four sails may provide an optimum combination of wind capture and solar exposure.

There is no single optimal shape of the sail. It can take many different forms, from a flat, linear construct or panel, to a parabolic arc, circular arc or bi-circular arc, each considering various parameters of the section shape, girth, entry and exit angles or radii.

The configuration, number and shape of the sails may change to suit the desired application. Variations based on a number of factors, including, but not limited to, wind speed, weather conditions, location, desired power output and site location (for permanent mount applications).

In one embodiment of the present invention, the sails of the hybrid wind-solar device can be made from solid photovoltaic panels. The solar absorption portion of the device can include any exterior surface exposed to direct or indirect sunlight. The sail design is based on optimizing the device's ability to capture wind energy, with a solar capture substrate integral to, or, attached to all or any part of the exterior surface.

Alternately, the sails of the hybrid wind-solar device can be made from photovoltaic panels, cells, discs, skins, films, sprays or any combination thereof, and may be applied to any or all of the exterior surfaces of the device. Such alternate construction of the device can be made from a variety of plastics, thermoplastics, nylons or non-ferrous metals.

Photovoltaic and other substrates with the ability to capture solar energy (photons) may be applied to any or all of the exterior surfaces of the device in a variety of ways. Current photovoltaic materials can be attached with clips, glue, rivets or other fastening system know in the art. Some new photovoltaic materials are flexible enough to adhere to any surface in a multiplicity of methods, or can be sprayed on, irrespective if the surface is flat or curved.

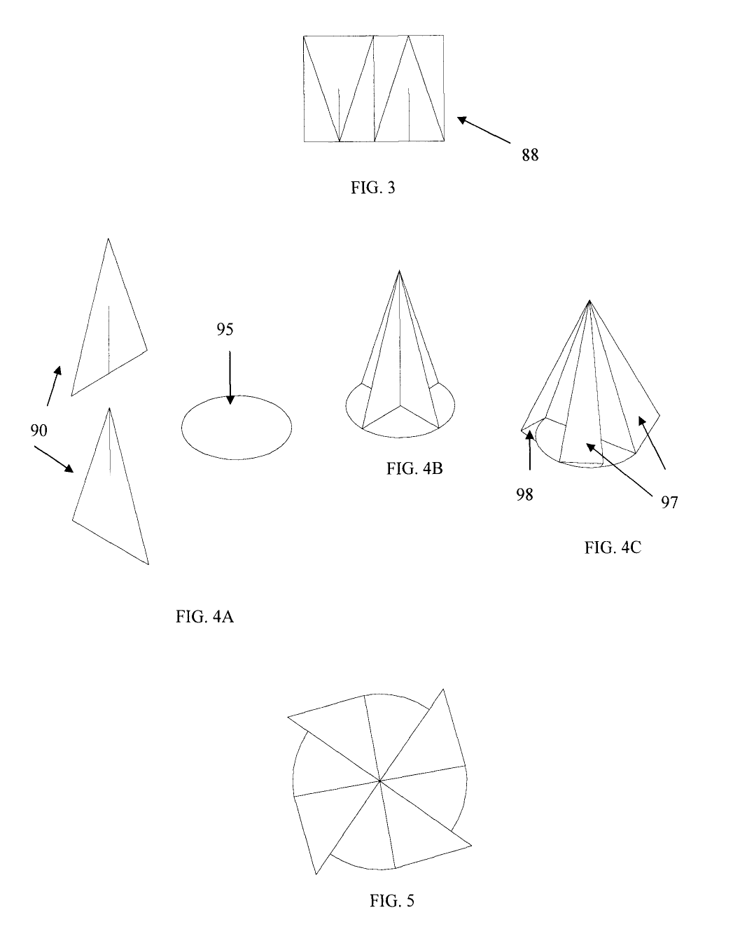

An example of constructing a four-sail wind-capture assembly is shown in FIGS. 3 and 4A-4D

FIG. 3 illustrates a template or pattern (88) for cutting components required to make the body of a wind-capture assembly with 4-sails for attachment to a base. The body can be a rigid photovoltaic solar panel, whereby the solar capture is integral to the design of the invention, so there is not a separate “solar portion” to be assembled. This design allows for full usage of the raw material whether it is rigid PV solar panels, plastic, thermoplastic or non-ferrous metals.

In an alternate embodiment, photovoltaic panels, cells, discs, skins, films, sprays or any combination thereof, may be applied to any or all of the exterior surfaces of the hybrid wind-solar device body material while the raw material is in its flat state as shown in FIG. 3. The affixing by clips, glue, adhesive, heat, pressure, perforation, lamination or any other means known in the art, is based upon the type of raw material used for the hybrid wind-solar device body and the chosen form of photovoltaic to be used in each application. If the construction is not comprised of solid solar panels, alternate construction of the device can be made from a variety of plastics, thermoplastics, nylons or non-ferrous metals.

The individual components depicted in the template or pattern of FIG. 3 can be cut using any commercially acceptable method in the craft to perform such a task on specific materials.

Metals may be cut to specific size requirements by sawing, shearing, cutting, laser cut, EDM cut, water jet, scoring, blanking or other methods known in the art, Computerized Numerical Controlled tool path, or any similar means known in the art, can be used.

Plastics may be made to specific size requirements by sawing, cutting, water jet, forming, moulding, or any other means known in the art.

Rigid PV Solar Panels can be custom made to specific size requirements as per the template or pattern. Flexible PV Solar Panels may by cut, sliced or formed to conform to the template or pattern.

FIGS. 4A-4C depict the basic components of a wind-capture body in an exploded view prior to the assembly process. The two triangular panels (90) shown in FIG. 4A, are the centre fins or sails of an embodiment of the hybrid wind-solar device. They are slotted to allow them to easily slide into relative position with each other creating an “X” shape if viewed from above.

The centre fins are secured at the base disc panel (95), which when completed, is shown in FIG. 4B.

In FIG. 4C, four triangular panels (97) are affixed to the centre fins at an angle of between about 30′ and about 150′, but preferably at about 90′ to the centre fins to enable the most effective wind capture. A small triangular bracket (98) can be used attach the bottom of these four panels to the base disc panel, thereby creating four distinct cavities that encapsulate and capture the wind, unlike other kinetically-driven turbines.

When fully assembled the wind-capture assembly resembles a pinwheel when viewed from above, as depicted in FIG. 5.

The energy captured by the wind-capture assembly (consisting of both solar and wind energy) can be transferred, for example, to a power reservoir such as a battery bank, or fed directly into an electrical grid network, or diverted to an emersion heater for water. If electrical load is not required, the resulting energy can be dissipated into a grounded terminus.

Solar and wind energy can be converted to direct current (DC) and stored in a battery bank as DC current at a specified voltage range, to be used as required at some time in the future. The solar and wind energy can also be converted to AC current, and tied directly to an electrical grid, or conditioned for direct use in an AC appliance.

Solar energy is collected through a photovoltaic substrate, or some other material that can convert light into electrical energy. The substrate is attached or applied to the outer surface of the hybrid wind-solar device; where direct or indirect light, (typically but not limited to sunlight) impinges photons on the substrate, causing electrons to flow. In turn, a DC electrical current is created that flows through a copper or other type of conductor through an electrical circuit where it is either used by an electrical load, or stored in a battery. The electrical circuit may contain a range of components, including a charge controller, inverter, switch, capacitor or other passive and active components to manipulate or condition the current for a desired outcome.

Wind energy is captured as a moving air mass (wind) or some other motive force acts upon the wind-capture assembly, causing it to rotate or spin, which in turn drives an electrical generator.

In conventional windmills or wind turbines, the device must be able to adjust its position to expose the largest cross section of their blades to the wind, in either an upwind or downwind configuration. This can prove troublesome in many installations where the area required for a wind turbine to orient itself into the wind limits their use in many applications. The hybrid wind-solar device of the present invention is designed to accept and accommodate wind coming in any direction.

Conventional windmills or wind turbines create energy from dynamic lift caused by kinetic energy from the wind passing over an airfoil (blade) thereby initiating rotation. If a cross-section of the swept area of by conventional 3-blade wind turbine is examined, it is evident that very little of the available wind moving through the swept area comes into contact with the blades. The area of the blades in relationship to the swept area is less than 3%; that is, up to 97% of the available energy from the wind passes through between the blades without converting any of its kinetic energy to electricity.

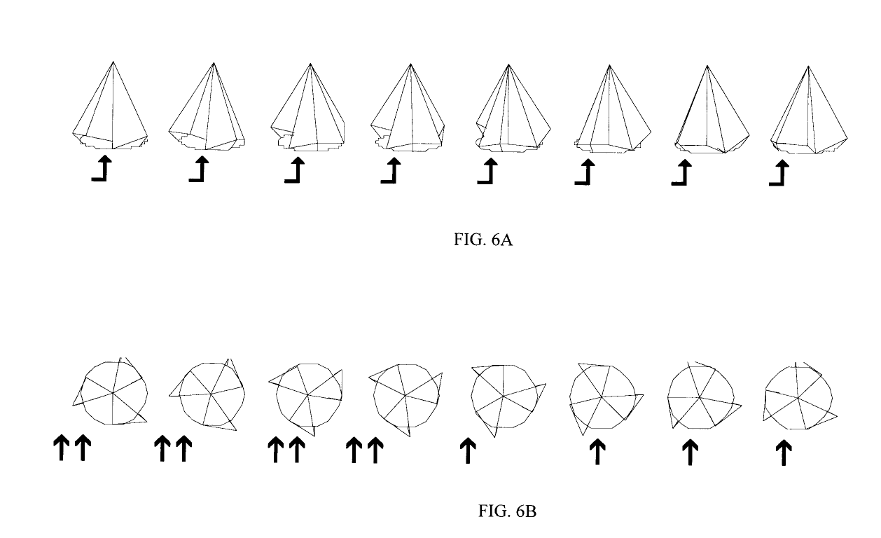

Unlike conventional wind generating devices, the present hybrid wind-solar device captures the wind and all of its potential and kinetic energy by encapsulating it within the “pockets” or “sails” on the downwind side, and by creating a low pressure area on the “upwind” side—similar to a yacht tacking into the wind. This is illustrated in FIGS. 6A and 6B, which respectively show perspective and top plan views of a 3-sail hybrid wind-solar device as it rotates due to kinetic energy from the wind.

For illustration purposes, the wind direction is “into” the device in FIG. 6A, and “up” in FIG. 6B, causing the device to rotate clockwise as wind is “captured” in the left side wind pockets or sails. By “encapsulating” the wind energy within the left side fin cavities, I the device is more efficient than a traditional wind turbine that has wind merely solely passing over the blade.

A result of the design is to provide for an efficient vertical wind turbine that captures and converts a high percentage of available kinetic energy from the wind into useable electricity. The consequence of this process is a device that turns on a central axis or vertical shaft, which is attached either directly or indirectly through mechanical means, to an electrical generator or machine capable of converting kinetic energy into electrical power.

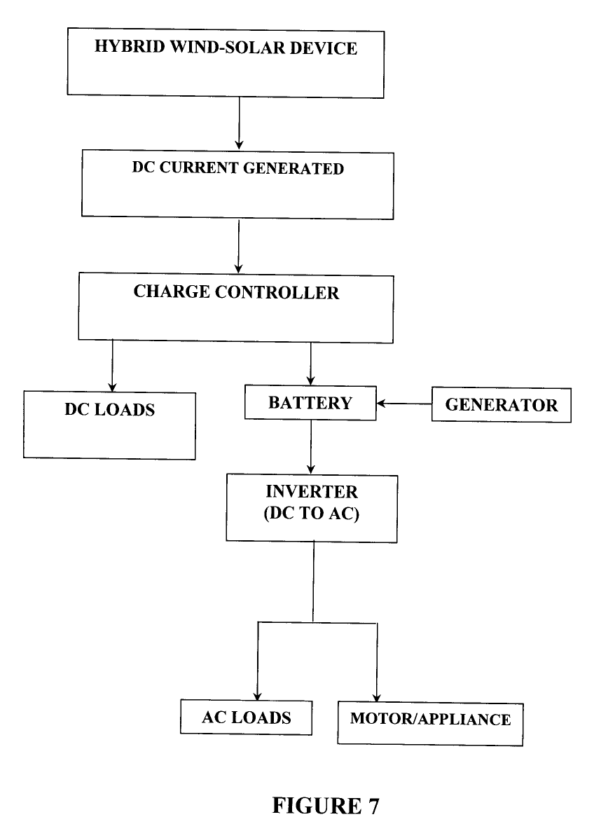

The wind-capture device acts as a prime mover to turn a generator shaft which is typically attached to an armature with a set of windings on an iron core. Through electromagnetic induction, the rotating shaft causes a voltage to be induced in the conductor, resulting in an electromotive force (EMF) and electron flow. The resulting current is typically direct or DC, and is sent through an electrical circuit that conditions and controls the current as required, prior to entering a battery for storage. An AC output can also be used directly or indirectly after some signal conditioning through an inverter as shown in an exemplary circuit diagram of FIG. 7.

The hybrid wind-solar device requires only one energy management system for wind and solar energy, as discussed below. FIG. 7 is a schematic representation of a basic circuit between a hybrid wind-solar device and other system components.

The hybrid wind-solar device provides for a direct current DC stream of electricity from either or both wind and solar generation, and the current passes through a Charge Controller or “EMS” Energy Management System. The purpose of the “EMS” is to regulate the amount of output from the hybrid wind-solar device entering the battery system to ensure there is no fear of explosion or other dangerous result from the batteries being over charged. The EMS ensures that the current is diverted into a “phantom” or “diversion” load whenever the batteries have attained peak charge, which can be usually about 2V above the rated output of the battery bank.

A simple “household” type system represented by the circuit of FIG. 7 has the inclusion of a standby or backup generator which can be used as a safety system to ensure the household will still be able to generate needed electricity in the event of a catastrophic failure to the hybrid wind-solar device or the EMS.

The circuit of FIG. 7 is exemplary of a “fixed, terrestrial” installation, and not a mobile or remote generating system. Alternate circuit arrangements can be made for a mobile generating system.

The hybrid wind-solar device can be stationary, or can be placed on vehicles such as trucks, trains and busses.

Non-limiting examples of uses of a stationary hybrid wind-solar device include: placement on a lamp post to provide illumination from electricity generated from the device; on a building roof to provide electricity for the building or occupants; on a cellular or microwave tower to provide electricity to the repeater signal for cell phones; or in any suitably windy and sunny location to use the electricity locally, or feed it into an electrical grid.

Non-limiting examples of uses of a mobile hybrid wind-solar device include: placement of a device on a small trailer to be towed to a remote location where electricity is needed; or towed to disaster sites or as a support for forward deployed troops needing power. In addition, the hybrid wind-solar device spins and generates electricity while in transit, which allows for use of power on demand. The energy generated while in transit is available in fully charged batteries when arriving on the scene. Mobile, green energy, on demand, can purify water, provide light, power communications, etc.

In case the hybrid wind-solar device is placed in a stationary or fixed location and there is an absence of wind to provide rotation to generate electricity from conversion of kinetic energy, no electrical generation occurs from the wind. During these irregular interruptions in wind generation the hybrid wind-solar device is able to generate solar energy from the various types of photovoltaic panels, skins, membranes, cells or coatings. Depending upon the time of day, the amount of solar generation varies depending upon the area of solar cells exposed to the sun. Around high noon, the entire surface of the hybrid wind-solar device is exposed to direct or indirect light photons. Solar energy capture is not dependant on the hybrid wind-solar device spinning. Solar energy is captured as a result of the photovoltaic panels being exposed to light, typically sunlight, and can generate electricity from light whether the device is spinning or not.

Although embodiments of the invention have been described above, it is not limited thereto and it will be apparent to those skilled in the art that numerous modifications form part of the present hybrid wind-solar device insofar as they do not depart from the scope of the claimed invention.

### CONCLUSION

The foregoing has constituted a description of specific embodiments which are only exemplary. The invention in its broadest, and more specific aspects, is further described and defined in the claims which now follow.

1. A renewable energy device comprising:
a) a wind-capture assembly comprising two or more rigid wind encapsulation pockets distributed circumferentially around a central axis thereof, each wind-encapsulation pocket comprising:
i) a base perpendicular to the central axis;
ii) a first member parallel to the central axis, the first member perpendicular to the base;
iii) a second member inclined towards the central axis, the second member adjacent to the first member and proximate the base; and
iv) a third member adjacent the second member and adjacent the base;
and
b) a generator assembly comprising an anchoring base, an electrical generator and an output shaft;
the wind-capture assembly rotatably mounted on the output shaft and coupled thereto; the renewable energy device configured to convert energy harnessed by the wind capture assembly to electrical energy, wherein:
the second member of each wind encapsulation pocket deflects incoming wind away from the first member of an adjacent wind encapsulation pocket; and
interaction of the two or more rigid wind encapsulation pockets with wind induces rotation of the wind-capture assembly and generator assembly around the central axis.

2. The renewable energy device of claim 1, wherein the wind capture assembly has:
a) a cross-sectional area transverse to the central axis;
b) a first extremity along the central axis; and
c) a second extremity along the central axis;
such that the cross-sectional area decreases from the first extremity to the second extremity.

3. (canceled)

4. (canceled)

5. The renewable energy device of claim 1, wherein the number of rigid wind encapsulation pockets is three or four.

6. The renewable energy device of claim 1, wherein the wind-capture assembly further comprises a solar-energy capture means on an outer surface thereof, with the outer surface of the wind capture assembly directly exposed to sunlight throughout daylight hours.

7. The renewable energy device of claim 6, wherein the solar-energy capture means is selected from the group consisting of solar panels, photovoltaic panels, cells, discs, skins, films, sprays and any combination of thereof.

8. The renewable energy device of claim 7, wherein the solar-energy capture means are flexible or rigid solar panels.

9. (canceled)

10. A hybrid wind-solar energy device comprising:
a) a wind-capture assembly comprising:
i) two or more rigid wind encapsulation pockets distributed circumferentially around a central axis thereof, each wind-encapsulation pocket comprising:
1) a base perpendicular to the central axis;
2) a first member parallel to the central axis, the first member (90) perpendicular to the base;
3) a second member inclined towards the central axis, the second member adjacent to the first member and proximate the base; and
4) a third member adjacent the second member and adjacent the base;
ii) a solar-energy capture means on an outer surface of the wind-capture assembly;
and
b) a generator assembly comprising an anchoring base, an electrical generator and an output shaft;
the wind-capture assembly rotatably mounted on the output shaft and coupled thereto;
wherein:
the second member of each wind encapsulation pocket deflects incoming wind away from the first member of an adjacent wind encapsulation pocket;
interaction of the two or more rigid wind encapsulation pockets with wind induces rotation of the wind-capture assembly and generator assembly around the central axis; and the outer surface of the wind capture assembly is directly exposed to sunlight.

11. The hybrid wind-solar energy device of claim 10, wherein the wind capture assembly has:
a) a cross-sectional area transverse to the central axis;
b) a first extremity along the central axis; and
c) a second extremity along the central axis;
such that the cross-sectional area decreases from the first extremity to the second extremity.

12. (canceled)

13. The hybrid wind-solar energy device of claim 10, wherein the solar-energy capture means is selected from the group consisting of solar panels, photovoltaic panels, cells, discs, skins, films, sprays and any combination of thereof.

14. (canceled)

15. (canceled)

16. The hybrid wind-solar energy device of claim 10, wherein the number of rigid wind encapsulation pockets is three or four.

17. (canceled)

18. A method for generating electricity using a hybrid wind-solar device, the method comprising:
a) providing a wind-capture assembly for capturing wind energy, the wind-capture assembly comprising two or more rigid wind encapsulation pockets distributed circumferentially around a central axis thereof, each wind-encapsulation pocket comprising:
i) a base perpendicular to the central axis;
ii) a first member parallel to the central axis, the first member perpendicular to the base;
iii) a second member inclined towards the central axis, the second member adjacent to the first member and proximate the base; and
iv) a third member adjacent the second member and adjacent the base;
with the second member of each wind encapsulation pocket deflecting incoming wind away from the first member of an adjacent wind encapsulation pocket;
b) rotatably coupling the wind-capture assembly to a generator assembly, the generator assembly comprising an anchoring base, an electrical generator and a vertical out shaft;
c) providing solar-capture means on an outer surface of the wind-capture assembly, the outer surface of the wind-capture assembly being exposed to sunlight;
d) affixing the combined wind-capture assembly and generator assembly via the anchoring base to a surface;
e) inducing rotation of the wind-capture assembly and generator assembly around the central axis by interaction of wind with the two or more wind pockets; and
f) providing electrical circuitry to convert energy harnessed by the wind capture assembly to electrical energy.

19. The method of claim 18, wherein the wind capture assembly has:
a) a cross-sectional area transverse to the central axis;
b) a first extremity along the central axis; and
c) a second extremity along the central axis;
such that the cross-sectional area decreases from the first extremity to the second extremity.

20. (canceled)

21. The method of claim 18, wherein the solar-energy capture means is selected from the group consisting of solar panels, photovoltaic panels, cells, discs, skins, films, sprays and any combination of thereof.

22. (canceled)

23. (canceled)

24. The method of claim 18, wherein the number of rigid wind encapsulation pockets is three or four.

25. (canceled)

26. The renewable device of claim 1, wherein: the second member is tangential to the base; and the third member is perpendicular to the central axis and co-planar with the base.

27. The hybrid wind-solar energy device of claim 10, wherein: the second member is tangential to the base; and the third member is perpendicular to the central axis and co-planar with the base.

28. The method of claim 18, wherein: the second member is tangential to the base; and the third member is perpendicular to the central axis and co-planar with the base.
